(19) United States
(12) Patent Application Publication
(10) Pub. No.: US 2026/0118457 A1
(43) Pub. Date: Apr. 30, 2026

(54) NMR APPARATUS WITH EFFICIENT CURRENT SOURCE

(71) Applicant: BRUKER SWITZERLAND AG, Fällanden (CH)

(72) Inventors: Michael SCHENKEL, Bäretswil (CH); Stefan HEGNAUER, Hombrechtikon (CH); Martin ZELLWEGER, Frauenfeld (CH)

(21) Appl. No.: 19/150,608

(22) PCT Filed: Jan. 26, 2024
(86) PCT No.: PCT/EP2024/051964

§ 371 Date: Aug. 27, 2025

(30) Foreign Application Priority Data
Feb. 20, 2023 (DE) 10 2023 201 434.3

(51) Int. Cl. G01R 33/3875

(52) U.S. Cl. CPC G01R 33/3875

(57) ABSTRACT

An NMR apparatus (10) with an NMR magnet system for generating an NMR magnetic field, which comprises an NMR coil (11) for modifying the magnetic field, and with a stable and low-noise current source that supplies the NMR coil with electrical current, comprising a linear current controller (12) that is electrically connected to a first end of the NMR coil, is characterized in that the current source comprises a digital voltage source (13) using switching technology, which is connected to a second end of the NMR coil, such that the NMR coil, as an electrical consumer, is connected between the linear current controller and the digital voltage source, that the current controller is connected to the digital voltage source via a control line (14) for controlling the electrical voltage, and that the linear current controller regulates the digital voltage source such that the voltage on the side of the linear part of the arrangement lies in a preselected operating range, so that the lowest possible electrical power is consumed in the linear part of the arrangement. This allows the NMR coil to be supplied with power in an adjustable, stable and low-noise manner with high electrical efficiency, while the homogeneity of the NMR magnetic field is kept stable and constant even under changing external conditions.

The invention relates to an NMR apparatus having a magnetic coil system for generating a homogeneous magnetic field, which comprises at least one NMR coil for modifying the NMR magnetic field, and comprising a stable current source which is configured to supply the NMR coil with electric current and which comprises a linear current controller that is electrically connected to a first end of the NMR coil, wherein the current source comprises a digital voltage source which is electrically connected to a second end of the NMR coil such that the NMR coil is connected as an electric consumer between the linear current controller and the digital voltage source, and wherein the linear current controller is connected to the digital voltage source via a control line for controlling the electric voltage.

An NMR apparatus having these features is known from reference [0].

NMR apparatuses having magnetic coil systems for generating a homogeneous magnetic field have already been in use across the world since the 1960s. An example is disclosed in DE 101 04 365 C1 (=reference [1]), for example.

A stable and low-noise current source, which is designed to supply an NMR coil in such an NMR apparatus with electric current and which comprises a linear current controller that is electrically connected to a first end of the NMR coil, is described in detail in the applicant's technical manual entitled “BSMS System for AVANCE NEO”, version 002, chapter 10 “SCB20”, sub-chapters 10.1-10.4, pages 83-90 (=reference [2]).

### TECHNICAL BACKGROUND OF THE INVENTION

The present invention relates quite generally to the field of nuclear magnetic resonance (NMR), and in particular to cooled NMR magnet systems that are generally superconductive during operation and in which the homogeneity or strength of the NMR magnetic field is further improved or varied by an NMR coil.

NMR spectroscopy is a widely used and powerful method of instrumental analysis used to analyze the electronic environment of individual atoms and the interaction of the individual atoms with adjacent atoms in a substance to be analyzed, such as a hydrocarbon molecule or a bioinorganic coordination compound. In this way, for example the composition, structure and dynamics of the substance to be analyzed can be made clear, and the concentration of the substance to be analyzed can likewise be determined.

In an NMR measurement, the substance is exposed to a strong static, homogeneous magnetic field Bo, which aligns the nuclear spins in the substance. High-frequency electromagnetic pulses are then radiated into the substance to be analyzed. The high-frequency electromagnetic fields generated in this way are detected in the NMR spectrometer. Information about the properties of the analyzed substance can then be obtained from this.

Both in high-resolution magnetic resonance spectroscopy and in magnetic resonance imaging, the requirements for magnetic field homogeneity are very high. In order to achieve the homogeneity specifications, electrical cryoshims are frequently used. Their coils generate elementary field profiles. When provided with suitable currents, they can improve the homogeneity of the NMR magnet at the sample location and thus increase the resolution of the measurement.

A high-resolution NMR spectrometer with a superconducting NMR magnet coil system, which is cooled to cryogenic temperatures using a pulse tube refrigerator and which is arranged within a vacuum vessel in the cold region of a cryostat, is described in EP 0 780 698 B1 (=reference [3]).

Sometimes, cold ferromagnetic material (for example, iron alloys or steel alloys) is also used as a shim element for improving homogeneity, as described, for example, in DE 10 2015 225 731 B3 (=reference [4]). Regardless of how a magnet is cold-shimmed, a residual inhomogeneity remains at the end and must be corrected by means of a further shim system, which comprises shim elements arranged outside the vacuum vessel, typically in the magnet bore. These shims, like cryoshims, can comprise either shim coils through which shim currents flow or ferromagnetic material or a combination of the two.

Current shim current sources for NMR apparatuses are based on analog circuit technology. These are usually stable and low-noise, but due to the high voltages and high currents applied at the same time in the current control loop, they are very inefficient, i.e., a lot of waste heat is generated.

Reference [1] already cited at the outset discloses a generic NMR apparatus with respect to the present invention, having all the feature complexes defined at the outset, including a shim system as an electric consumer of the current source in question. However, this NMR apparatus also suffers from the above-described problems regarding efficiency due to the high voltages and high currents simultaneously applied in the current control loop, i.e., a relatively large amount of waste heat is generated during NMR operation.

This is also clear from reference [2] likewise already cited above, which discloses in detail the stable and low-noise and optimal-at least up until now -current source that can be used in the NMR apparatus of reference [1]. In chapter 10 of reference [2], starting on page 83, the currently used current source “SCB20” is described in more detail. In particular, the block diagram on page 86 shows that here too the entire power is provided by the linear part of the arrangement.

This previous prior art, which is closest to the present invention, provides the required current from the supply voltage in an entirely linear fashion. If the resistive component of the load-including the supply cable-is small, the power component of the voltage not required is dissipated in the linear amplifier and converted into heat. On the one hand, this wastes electric current and puts more strain on the power supply than is actually necessary. On the other hand, this requires a special heat dissipation device in the NMR apparatus, usually a heat sink, which, however, makes the current source excessively large. Furthermore, typical low-noise linear amplifiers that can operate in the required voltage range are located in the audio range. However, these increasingly compete with class D amplifiers optimized for audio applications, which is why it can be assumed that sooner or later the low-noise linear amplifiers used here will no longer be commercially available, or will at least soon no longer be easily available like they were before. Audio class D amplifiers do not fulfill the specific purpose of supplying current to an NMR coil either, which requires a continuous current.

### OBJECT OF THE INVENTION

In contrast, the object of the present invention is that of modifying the current source for an NMR coil in an NMR apparatus having the features defined at the outset by means of particularly readily available, easily accessible technical means and as cost-effectively as possible such that the NMR coil is supplied with an adjustable, stable, low-noise current with the highest possible electric efficiency, wherein the very high degree of homogeneity of the NMR magnetic field is kept as stable and constant as possible, especially for use as a current source for shim coils, but also for other applications in the field of NMR.

### BRIEF DESCRIPTION OF THE INVENTION

This relatively complex problem is solved by the present invention in a surprisingly simple and effective manner in that the current source is low-noise and the digital voltage source is implemented such that it uses switching technology, and in that the linear current controller is designed to control the digital voltage source in such a way that the voltage on the side of the linear part of the arrangement is in a preselected working range so that the smallest possible amount of electric power is consumed in the linear part of the arrangement.

By using the current source modified according to the invention, the NMR coil in the NMR apparatus can now be supplied with current with particularly high electric efficiency.

The solution according to the invention comprises a highly efficient, variable digital voltage source that uses switching technology, an adjustable stable and low-noise linear current controller that uses mixed analog and digital technology, and the NMR coil that, as an electrical load, is supplied with power by this current source. The arrangement according to the invention is characterized by a high inductive component of the electrical impedance of the load compared to the resistive component. The NMR coil as an electrical load is deliberately arranged between the voltage source and the current controller in the circuit. Due to the high inductive component of the load in the form of a coil, high-frequency interference from the switching digital voltage source is kept at a distance from the sensitive, low-noise linear current controller.

An essential feature of the solution according to the invention consists in the highly efficient provision of a voltage at an electrical terminal of the NMR coil acting as a load. This voltage is controlled so as to minimize power loss and thus waste heat in the linear current controller connected to the other electrical terminal of the load. Together with the highly efficient generation of voltage, the efficiency of the overall system consisting of the digital voltage source, linear current controller and the NMR coil as an electrical load is optimized, thus minimizing the power loss occurring during NMR operation.

By arranging the inductive load between the digital voltage source and the linear current controller, interference caused by the necessary switching operations in the voltage source is filtered and kept at a distance from the current controller. As a result, this allows for high purity of the preset current through the linear current controller and thus through the NMR coil as a load. The high purity of the preset current and thus of the magnetic field generated in the NMR coil is an essential prerequisite for successful NMR experiments.

For a better understanding of the present invention, it should be noted that for the changes proposed according to the invention with respect to the closest prior art, good commercial availability of the amplifier, reduced space requirement of the arrangement and its significantly increased electric efficiency are especially advantageous.

Ideally, the current would be provided directly switched from the supply voltage. However, the low noise required in NMR applications still requires a linear controller, which is also desirable for stability. However, this is only intended to cause a limited voltage drop, which means that a small proportion of the electric power is consumed in the linear controller. In addition, amplifiers with a smaller maximum voltage swing than the supply voltage are more readily commercially available on the market.

If the linear current controller is connected directly behind the switching voltage source, the linear controller must operate on the fly.

If multiple efficient current sources are used for an NMR spectrometer, such as for the operation of multiple shim coils, the linear controller of each current source would have to be designed separately, isolated separately and separately supplied with a supply voltage. Often more than one switching power supply is required for each current source, e.g., one per supply terminal of the linear controller, sometimes even more. On the one hand, this is associated with considerable costs, and, on the other hand, this solution requires so much space that the desired size-related advantage as a result of improved efficiency is no longer achieved.

The core idea of the invention is therefore to attach the linear controller to the ground side of the coil, while on the other side the digital voltage source provides a voltage potential above or below the ground voltage. “Ground” is understood here to mean the electrical ground or ground potential.

Especially when using multiple efficient power sources, their linear controllers can then use the same supply. The actuation of the DACs, ADCs and operational amplifiers can be carried out via multi-channel components that do not need insulating. These component parts are, for example, semiconductor component parts that contain a plurality of ADCs, DACs and/or operational amplifiers with corresponding connection contacts. In this way, functions of different linear current controllers can be combined in common component parts. This significantly saves space and costs. The large inductance of the NMR coil also helps to additionally filter the current before it reaches the sensitive linear controller.

The linear current controller can have a limited voltage range, sometimes much smaller than that of the digital voltage source. This voltage range of the linear current controller must not be exceeded-in contrast to the closest prior art, where the current controller covers the entire voltage range.

In this case, the digital voltage source must be controlled such that this voltage range is maintained at the desired current. This also applies in the transient phase while the current through the NMR coil is brought to the target current. This is achieved by a slow change in the current through the linear current controller and-on the basis of a voltage measurement on the ground side of the NMR coil-the digital readjustment of the voltage generated by the digital voltage source.

When the target current is reached, the digital voltage source is adjusted within its digital grid so that the voltage drop across the linear part of the current source is as small as possible, with a defined small margin for the control of the linear current controller. This means that for “positive” currents the voltage is at the lower end, and for “negative” currents it is at the upper end, of the voltage range of the linear current controller. Here, “positive” refers to a current that flows into the linear part of the current source.

In order to further explain the present invention, some key terms will be explained in more detail below:

### Stable and Low-Noise Current Source:

The effectively measured noise for a 1-A and 10-Ohm resistive load of 1 Hz-100 Hz is less than 1 uArms, and of 1 Hz-200 kHz is less than 20 uArms. The requirement of the present invention is to keep the noise as low as possible with reasonable effort. For this to be possible, the entire circuit needs sufficiently good interference suppression across the entire frequency range. This will also be explained in detail below in the explanations relating to the pre-controller.

### Linear Current Controller:

A current controller with a linear output stage is a linear controller. The linear current controller can be analog and/or digital. In the case of the present invention, it is both: a “fast” analog current controller is actuated by a slower digital control loop.

The following limits should be aimed for in regard of the stability of the linear current controller: Gain drift<11 ppm/° C. and offset drift<+/−1 uA/° C.

### Digital Voltage Source That Uses Switching Technology:

A digital voltage source that uses switching technology is a DC to DC converter that efficiently converts a supplied DC voltage into another DC voltage by using switching elements and one or more energy storage devices. In the case of the present invention, a step-down converter is normally used, thus achieving a reduction with respect to the supply voltage.

### PREFERRED EMBODIMENTS AND DEVELOPMENTS OF THE INVENTION

In a very particularly preferred class of embodiments of the NMR apparatus according to the invention, the digital voltage source can be operated in a pulsed manner.

The mode of operation is that of a digital voltage source that uses switching technology. Switching voltage sources can be very efficient and therefore have low heat generation while providing the same output power.

In preferred developments of this class of embodiments, the pulse/switching frequency of the digital voltage source is in a range between 10 kHz and 1 GHz, preferably between 30 kHz and 200 kHz.

At frequencies that are too low (<10 kHz), filter elements that are to be arranged between the digital voltage source and the NMR coil become too large and too slow. At frequencies that are too high (>1 GHz), switching losses become too high, efficiency decreases and too much heat is generated. However, the latter is constantly being improved through technological progress. Higher frequencies are in principle preferred because the filters can be smaller and/or better.

In further advantageous developments of this class of embodiments, the digital voltage source can be operated with pulse-width modulation. At a constant supply voltage of the digital voltage source, the duty cycle (ratio of the switch-on time to the period duration) is increased or decreased. The duty cycle thus determines the voltage applied to the NMR coil.

At a given duty cycle, a defined output voltage is generated from an existing input voltage. The use of pulse-width modulation enables simple implementation and good predictability of the output voltage of the digital voltage source. In addition, the pulse frequency of the digital voltage source specifies a clearly defined fundamental frequency that can be filtered by fixed components.

Other, likewise advantageous developments are characterized in that the digital voltage source has a filter (usually an analog filter) with at least one inductive element, in particular one or more coils, and with one or more capacitive elements, in particular capacitors, connected in parallel, to ground, wherein the filter is designed to smooth the voltage of the pulsed digital voltage source. Preferably, this filter is arranged directly between the digital voltage source and the NMR coil.

The first element of the filter is, for example, a PWM storage choke and a capacitor to filter out the DC component of the square wave voltage of the digital voltage source. A snubber can also be provided for damping the filter.

The second element comprises, for example, a filter choke and a capacitor for improved filtering of the PWM frequency as well as another snubber for damping the filter. In this case, the PWM frequency is the pulse frequency of the pulsed voltage source.

The first element should contain an inductive and/or capacitive element. The second element could also be implemented differently than with an LC element, e.g., linearly (which may, however, correspondingly mean more loss). Or the second LC element is integrated in the first element, which means it could be omitted. Accordingly, the first element would then be slightly larger. The division into two parts has the advantage that the second element can be further away from the PWM element (which, for example, serves multiple current sources at the same time) and thus the individual voltages can be better shielded against interference from the other current sources.

A further advantageous embodiment of the NMR apparatus according to the invention is characterized in that the digital voltage source is designed to provide both negative and positive voltage values.

The direction of the current through the NMR coil depends on the sign of the voltage values. This is advantageous because it allows the magnetic field of the NMR coil to be influenced and varied in both directions.

Particularly preferred is also a class of embodiments of the invention which is characterized in that the linear current controller comprises a shunt resistor and an A/D converter across this resistor for measuring the current flowing through the NMR coil.

Since the current is digitally set, it must also be digitally measurable.

A common way of measuring the current is by using a shunt resistor. Alternative current measurement methods are not sufficiently stable or precise.

Developments of these embodiments in which the A/D converter is connected to a digital control unit are advantageous.

By appropriate programming of this digital control unit, the analog current controller can control the digital voltage source in such a way that the voltage on the side of the analog part of the arrangement lies in a preselected working range. This means that the analog part of the arrangement consumes a particularly small amount of electric power.

In the digital space, various control optimizations can be implemented as programs. Subsequent control adjustments are also easier.

The digital voltage source must be digitally addressed anyway, which is why a digital controller has advantages.

In another particularly preferred embodiment of the NMR apparatus according to the invention, the linear current controller comprises an electric amplifier for feeding current into the NMR coil.

The electric amplifier is mainly used to achieve the required low noise levels.

Particularly preferred are developments of the two embodiments of the invention described above, which are characterized in that the digital control unit is connected to the electric amplifier via a D/A converter and preferably to the digital voltage source via the control line.

The electric amplifier functions analogously; the digital control unit, however, functions digitally. In order to actuate the electrical amplifier, a D/A converter is used to cross the digital-analog boundary. This also allows the necessary stability and resolution to be achieved.

In a further, particularly preferred class of embodiments of the NMR apparatus according to the invention, the digital voltage source is actuated according to a fixed time grid. If multiple current sources are arranged spatially next to one another, their interference with one another can be reduced if the digital voltage sources are active at the same time.

By actuating the digital voltage source in a fixed time grid, interference between the plurality of similar, efficient power sources is avoided. The fixed time grid creates discrete voltage levels. These discrete voltage levels of the digital voltage sources are compensated for by the linear current controller.

In one class of particularly advantageous developments of these embodiments, an integer divisor of a measurement interval of the A/D converter is selected as the time grid, or the time grid is selected such that a digital filter element suppresses the frequency of the time grid as effectively as possible so that it does not interfere with the current through the NMR coil.

Common A/D converters already have this digital filter function integrated therein. The filter in the ADC can therefore be adjusted to match the grid, and/or vice versa.

An advantageous variant of this class of developments is characterized by the presence of at least one pre-controller for the voltage supply of the digital voltage source.

The pre-controller (“power supply stabilizer”), which is usually integrated in the digital voltage source, serves to further suppress interference in the mid-frequency range (10 Hz-10 kHz) that arise from the power supply of the voltage source. The PWM filters, on the other hand, only filter frequencies above 10 KHz.

Every current source is intended to be low-noise, to generate as little interference as possible over a wide frequency range and to be very stable (=preferably no interference at all at the lowest frequencies).

In the mid-frequency range, the effect of the linear controller is no longer good enough, and the analog filter does not work properly in this range either. In order to keep interference from the power supply of the digital voltage source in the mid-frequency range at a distance from the load, the supply voltage of the digital voltage source is therefore pre-controlled.

Further advantageous embodiments of the invention are characterized in that the current source is designed such that the electric current flowing through the NMR coil can be varied within the range of from −20 A to +20 A, in particular within the range of from −1 A to +1 A.

The current through the NMR coil connected as an electrical load that is within a given range according to the requirements of the NMR system can be adjusted with high resolution and accuracy (e.g., up to 20 bits) and, if necessary, changed over time. Together with the NMR coil, even the smallest changes in the NMR magnetic field of the NMR apparatus caused by external events can be corrected.

The following key data are typical for a stable and low-noise current source:
Switching frequency: >10 kHz (during pulsed operation)
Current: <+/−1 A per current source
Voltage supply: +/−24 V
Noise @1 A, 10 Ohm resistive load: 1 Hz-100 Hz: <1 uArms, 1 Hz-200 kHz: <20 uArms
Load: 0-20 Ohm, 0-1 mH
Resolution: >20 bit
Stability: Gain drift<11 ppm/° C. and offset drift<+/−1 uA/C

In practice, embodiments of the invention in which the NMR coil is designed as a coil for shimming the NMR apparatus and/or for homogenizing the NMR magnetic field generated by the NMR magnet system or for varying the NMR magnetic field, in particular by means of a flux pump, have proven particularly useful.

It may happen that, for example, when operating multiple shim coils, several dozen of such current sources are required, the current and voltage requirements of which are not known in advance. Only in the final application does it become clear which source must drive which shim coil with which current.

In the flux pump, the voltage is relatively small, but the maximum current is sometimes even higher. A flux pump in an NMR apparatus serves to compensate for a decrease in the main magnetic field of the NMR magnet system by inductive coupling.

Further advantages of the invention are found in the description and the drawing. Likewise, the features mentioned above and those detailed below can be used according to the invention individually or collectively in any combination. The embodiments shown and described are not to be understood as an exhaustive list, but rather have an exemplary character for the description of the invention.

### DETAILED DESCRIPTION OF THE INVENTION AND DRAWINGS

The invention is illustrated in the drawings and will be explained in more detail with reference to embodiments.

In the Drawings:

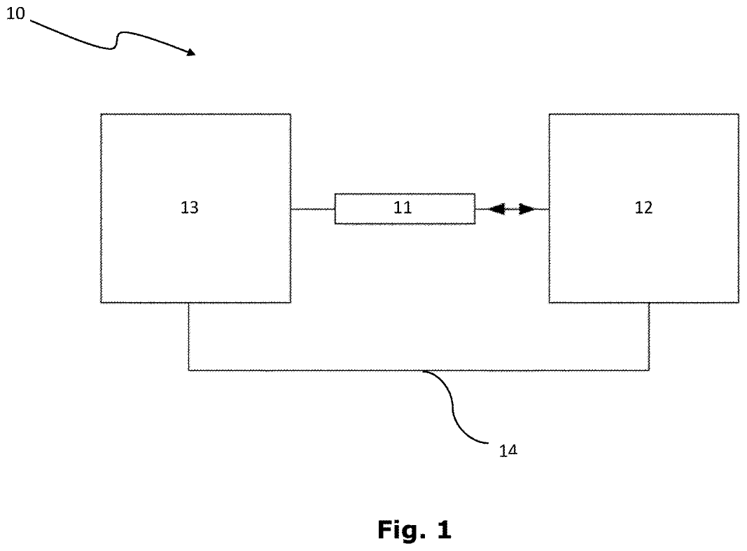

FIG. 1 shows a schematic block diagram of the essential parts according to the invention of an NMR apparatus modified according to the invention; and

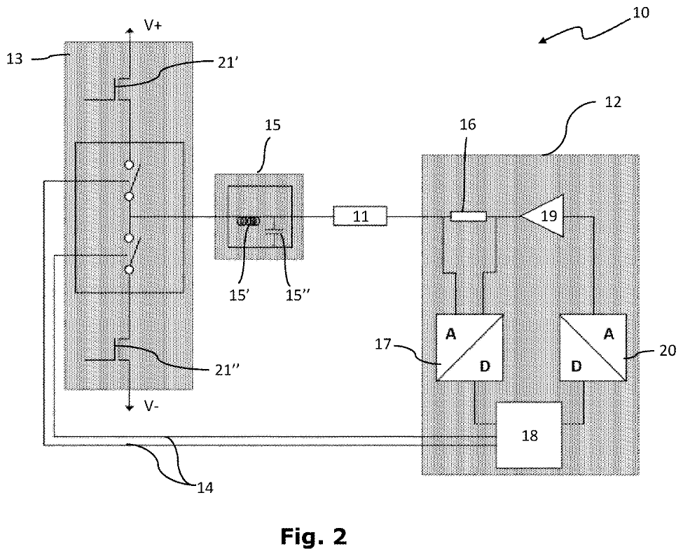

FIG. 2 shows a schematic block diagram of a preferred embodiment of the invention.

In general, the present invention relates to a modified NMR apparatus 10, which comprises an NMR magnet system (not specifically shown in the drawings) for generating a homogeneous magnetic field, which has at least one NMR coil 11 for modifying the NMR magnetic field. In addition, a stable and low-noise current source is provided, which is designed to supply the NMR coil 11 with electric current and which has a linear current controller 12 which is electrically connected to a first end of the NMR coil 11.

As shown in FIG. 1, the NMR apparatus 10 according to the invention is distinguished from the prior art in that the current source comprises a clocked digital voltage source 13 that uses switching technology, which is electrically connected to a second end of the NMR coil 11 so that the NMR coil 11 is connected as an electrical consumer between the linear current controller 12 and the digital voltage source 13. The linear current controller 12 is connected to the digital voltage source 13 via a control line 14 for controlling the electric voltage. According to the present invention, the linear current controller 12 is designed to control the digital voltage source 13 such that the voltage on the side of the linear part of the arrangement is in a preselected working range (e.g., 0 to 3.3 V) such that the smallest possible amount of electric power is consumed in the linear part of the arrangement.

As a rule, the digital voltage source 13 can be operated in a pulsed manner, with the pulse frequency being within a range of between 10 kHz and 1 GHz, preferably between 30 kHz and 200 kHz. In a specifically implemented embodiment of the invention, a frequency of 104.1666 kHz is used.

In particular, the digital voltage source 13 can be operated with pulse-width modulation. The level of the output voltage is determined by the pulse-width modulation of the digital voltage source 13. The linear current controller 12 determines the current through the NMR coil 11, in particular finely adjusts it. Only high-frequency interferences cannot usually be sufficiently controlled by the current controller 12.

FIG. 2 shows a block diagram of a particularly preferred embodiment of the NMR apparatus 10 according to the invention.

The digital voltage source 13 is designed to provide both positive and negative voltage values, which is evident in the drawings from the symbols V+ and V− at the two voltage inputs. Typically, these are voltages between +24 V and −24 V. This voltage range is therefore larger than the preselected voltage range of the linear component of the circuit.

As clearly shown in FIG. 2, the digital voltage source 13 in this embodiment has a filter 15 (hereinafter also “analog filter”) having at least one inductive element, in particular one or more coils 15′, and having one or more capacitive elements connected in parallel, to ground, in particular capacitors 15″. The filter 15 is designed to smooth the voltage of the digital voltage source 13. In FIG. 2, the filter 15 is shown spatially separated from the digital voltage source 13; however, it can also be integrated therein. In any case, it is arranged between the voltage source and the NMR coil.

In the embodiment shown, the linear current controller 12 comprises a shunt resistor 16 and an A/D converter 17 across this resistor for measuring the current flowing through the NMR coil 11. The A/D converter 17 is connected to a digital control unit 18.

Furthermore, the linear current controller 12 comprises an electric amplifier 19 for feeding current into the NMR coil 11.

The digital control unit 18 is connected via a D/A converter 20 to the electric amplifier 19 and preferably connected via the control line 14 to the digital voltage source 13.

The digital voltage source 13 is actuated according to a fixed time grid such that multiple current sources used at the same time do not interfere with one another. An integer divisor of a measuring interval of the A/D converter 17 (hereinafter also referred to as an “ADC”) can be selected as the time grid. However, the time grid can be selected such that a digital filter element suppresses the frequency of the time grid as effectively as possible. The measurement interval of the AD converter corresponds to the ADC frequency in the frequency domain.

If any PWM frequencies or any voltages generated therewith are permitted, all of these frequencies are present on the voltage signal from the digital voltage source, as well as mixed frequencies with the other current sources. These cannot be filtered out sufficiently well using the analog filter; such filters at least either have no space in the arrangement or are too expensive or consume too much power. Uncontrolled mixed frequencies could directly lead to interference in the NMR measurement. However, the stability of the currents is crucial for shim applications.

There should actually be a Nyqvist filter in front of the ADC to filter out frequencies above half the ADC frequency. However, since extremely precise measurements must be taken during NMR operation, this filter would produce too large an error, or the effort required for permanent recalibration would be too expensive/complex, if even possible. Therefore, a Nyqvist filter is usually not used. This creates mixed frequencies in the ADC, which cause a measurement error. Common sigma-delta ADCs have integrated digital filters that can suppress selected frequencies (and multiples thereof) very well.

The largest measurement errors occur where the largest disturbances are, i.e., especially at the PWM frequency of the digital voltage source (and multiples thereof), which cannot be perfectly filtered by the analog filter. The PWM frequency and ADC filter are therefore adjusted to match one another so that the ADC does not make any measurement errors due to PWM interference.

In the arrangement according to the invention, at least one pre-controller for the voltage supply of the digital voltage source 13 should be present. The embodiment according to FIG. 2 shows two pre-controllers 21′; 21″, which are shown here spatially integrated in the digital voltage source 13, but in other embodiments can also be arranged separately from the digital voltage source 13, such as the filter 15 in FIG. 2.

The current source of the NMR apparatus 10 modified according to the invention will generally be designed such that the electric current flowing through the NMR coil 11 can be varied within the range of from −20 A to +20 A, in particular within the range of from −1 A to +1 A.

In particularly important applications of the invention, the NMR coil 11 is designed as a coil for shimming the NMR apparatus 10 and/or for homogenizing the NMR magnetic field generated by the NMR magnet system. However, it can also be used, for example, to vary the NMR magnetic field. The device then acts as a flux pump.

The current level is determined by the linear current controller provided that the voltage source generates a voltage that, taking current and load into account, results in a voltage at the operational amplifier that is within its permissible range. Otherwise, the current is undefined, uncontrolled, not stable and not low-noise, and the current controller can be destroyed in the absence of protective circuitry. The current controller withstands less voltage during operation than the digital voltage source can generate.

Typically, the electric amplifier is designed as one or more interconnected operational amplifiers. Most operational amplifiers can source or sink current, i.e., the current can also flow into the apex of the triangle representing the operational amplifier in the circuit diagram, which in this case is called “positive”current.

At first glance, the ground is not relevant for the circuit:
A positive current flows from the +V supply, is converted to a lower voltage, flows through the NMR coil and then into the negative power supply of the operational amplifier.
A negative current flows from the positive power supply of the operational amplifier, through the NMR coil, into the digital voltage source and away through the −V power supply.
Here, the ground does not appear to begin with, which also makes sense since the same current can be achieved on both sides of the NMR coil with different potentials/voltages, as long as only the voltage difference remains the same.

But there are still boundary conditions, and this is where the ground plays a role again:
The voltage generated by the pulsed digital voltage source must be filtered/stabilized against any potential. This potential is advantageously the ground.
In order to save one power supply and to be able to actuate the operational amplifiers with reference to ground, the linear output stages, i.e., the power amplifiers, are not supplied symmetrically, i.e., the negative power supply of the power amplifier is the ground here.

However, the operational amplifier symbol in the block diagram does not only represent a single power amplifier. Normally, additional operational amplifiers that do not carry the entire current are required. These may then still require a +/− power supply, but this power supply does not need to supply as much current as the power amplifier power supply.

### LIST OF REFERENCE SIGNS

10 NMR apparatus
11 NMR coil
12 linear current controller
13 digital voltage source in switching technology
14 control line
15 filter
15′ inductive elements
15″ capacitive elements
16 shunt resistor
17 A/D converter
18 digital control unit
19 electric amplifier
20 D/A converter
21′; 21″ pre-controller LIST OF REFERENCES

Publications taken into consideration for the assessment of patentability:
[0] NICK ARRANGO ET AL:: Open-source, low-cost, flexible, current feedback-controlled driver circuit for local BO shim coils and other applications. Publication date: February 7, 2022. Source (URL: https://cds.ismrm.org/protected/16MProceedings/PDFfiles/1157.html) [searched on 07/27/2023]
[1] DE 101 04 365 C1≈GB 2 411 238 B≈US 2005/0174118 A1
[2] Applicant's technical manual entitled “BSMS System for AVANCE NEO”, version 002, chapter 10 “SCB20”, sub-chapters 10.1-10.4, pages 83-90
[3] EP 0 780 698 B1≈US 5,744,959 A
[4] DE 10 2015 225 731 B3≈EP 3 182 147 B≈US 9,766,312 B1≈CN 106898452 B≈JP 6340403 B

1. An NMR apparatus having an NMR magnet system for generating an NMR magnetic field, comprising:
at least one NMR coil for modifying the NMR magnetic field, and
a stable, low-noise current source which is configured to supply the NMR coil with electric current and which comprises:
a linear current controller electrically connected to a first end of the NMR coil that comprises an electrical amplifier for feeding current into the NMR coil, and
a digital voltage source designed in switching technology that is electrically connected to a second end of the NMR coil such that the NMR coil is interposed as an electrical load between the linear current controller and the digital voltage source, the linear current controller being connected to the digital voltage source via a control line for controlling an electrical voltage,
wherein the linear current controller configured to control the digital voltage source such that a voltage on a side of the a linear part of the current source is in a preselected working range so that a lowest possible electric power is consumed in the linear part of the current source.

2. The NMR apparatus according to claim 1, wherein the digital voltage source can be operated in a pulsed manner.

3. The NMR apparatus according to claim 2, wherein a pulse frequency of the digital voltage source is in a range between 10 kHz and 1 kHz.

4. The NMR apparatus according to claim 2, wherein the digital voltage source can be operated using pulse width modulation.

5. The NMR apparatus according to claim 2, wherein the digital voltage source has a filter having at least one inductive element, and or more capacitive elements, connected in parallel to ground, the filter being designed to smooth the voltage of the digital voltage source.

6. The NMR apparatus according to claim 1, wherein the digital voltage source is configured to provide both negative and positive voltage values.

7. The NMR apparatus according to claim 1, wherein the linear current controller comprises a shunt resistor and an A/D converter across said shunt resistor for measuring the current flowing through the NMR coil.

8. The NMR apparatus according to claim 7, wherein the A/D converter is connected to a digital control unit.

10. The NMR apparatus according to claim 8, wherein the digital control unit is connected to the electrical amplifier via a D/A converter.

11. The NMR apparatus according to claim 1, wherein the digital voltage source is actuated according to a fixed time grid such that multiple current sources used simultaneously do not interfere with one another.

12. The NMR apparatus according to claim 11, wherein the linear current controller comprises a shunt resistor and an A/D converter across said shunt resistor for measuring the current flowing through the NMR coil, and wherein an integer divisor of a measuring interval of the A/D converter is selected as the time grid.

13. The NMR apparatus according to claim 12, wherein at least one pre-controller is provided for a voltage supply of the digital voltage source.

14. The NMR apparatus according to claim 1, wherein the current source is configured such that the electric current flowing through the NMR coil can be varied within the a range of from −20 A to +20 A.

15. The NMR apparatus according to claim 1, wherein the NMR coil is configured as a coil for shimming the NMR apparatus and/or for homogenizing the NMR magnetic field generated by the NMR magnet system or for varying the NMR magnetic field.
